(19) United States
(12) Patent Application Publication
(10) Pub. No.: US 2005/0145922 A1
(43) Pub. Date: Jul. 7, 2005

(54) EEPROM and flash EEPROM

(76) Inventors: Joseph Farley, Villeneuve Loubet (FR); Jozef Mitros, Richardson, TX (US); Alec Morton, Plano, TX (US); Robert Todd, Plano, TX (US)

Correspondence Address: TEXAS INSTRUMENTS INCORPORATED, P O BOX 655474, M/S 3999, DALLAS, TX, 75265, US

(21) Appl. No.: 10/748,497

(22) Filed: Dec. 30, 2003

(51) Int. Cl. H01L 29/788

(52) U.S. Cl. 257/315

(57) ABSTRACT

An EEPROM memory cell uses PMOS type floating gate transistor formed in a n-well, where the floating gate is routed over a p− diffused region formed in the n-well to form a control capacitor. The PMOS floating gate transistor uses a p-type diffused region below the p+ active region forming the drain to provide a higher breakdown voltage. Cell programming can be performed through hot-electron injection, with the electric field across the control capacitor to aid injection into the floating gate. FN erasure is achieved by taking the potential of the n-well to the programming voltage while holding the potential of the control capacitor at a low voltage.

### CROSS-REFERENCE TO RELATED APPLICATIONS

Not Applicable

### STATEMENT OF FEDERALLY SPONSORED RESEARCH OR DEVELOPMENT

Not Applicable

### BACKGROUND OF THE INVENTION

1. Technical Field

This invention relates in general to semiconductor circuits and, more particularly, to an EEPROM and FLASH EEPROM design.

2. Description of the Related Art

Many mobile devices, such as mobile phones, PDAs (personal digital assistants), mobile computers and music players (such as MP3 players) rely on non-volatile semiconductor memory to maintain data and programs in the event of insufficient battery power. The most popular forms of semiconductor non-volatile memory are EPROMs (erasable programmable read only memory), which are erasable using UV light and EEPROMs (electrically erasable programmable read only memory), which are electrically erasable. One variation of an EEPROM is the FLASH EEPROM, which allows multiple memory cells to be erased at one time.

One time programmable EPROMs are relatively compact, but can only be erased using UV light, which makes them unsuitable in many situations. Early EEPROMs were fabricated using a multi-polysilicon process, forming a control gate above a floating gate. This process required multiple masks, longer process turnaround times, lower yields, higher costs, and lower reliability. More recently, a single polysilicon approach has been developed. A single polysilicon approach is especially suited for providing an EEPROM array in an integrated solution along with a processor and dynamic memory, where a second polysilicon would not be otherwise needed.

A problem with the single polysilicon process is the larger size of the cell. This can be a significant problem in an integrated solution, where other components have large die requirements.

Accordingly, a need exists for an EEPROM with a smaller cell size.

### BRIEF SUMMARY OF THE INVENTION

In the present invention, an electronically erasable read only memory includes a capacitor comprising a diffusion layer of a first conductivity type formed in well of a second conductivity type, an insulating layer overlying the diffusion layer and a floating gate overlying the diffusion layer. A MOS transistor comprises first and second active regions formed in the well, adjacent to an extended portion of the floating gate.

The present invention provides significant advantages over the prior art. First, the memory cell is very compact compared to other EEPROMs which require multiple wells. Second, the process is compatible with many other process technologies, without requiring additional polysilicon layers. Third, the cell can be programmed using either Fowler-Nordheim tunneling or hot electron injection. Fourth, the cell supports flash erasure.

### BRIEF DESCRIPTION OF THE SEVERAL VIEWS OF THE DRAWINGS

For a more complete understanding of the present invention, and the advantages thereof, reference is now made to the following descriptions taken in conjunction with the accompanying drawings, in which:

FIGS. 1a and 1b illustrate a plan view and a cross-sectional side views of a prior art EEPROM memory cell;

FIG. 2 illustrates a plan view of an EEPROM memory cell;

FIGS. 3 through 5 illustrate cross-sectional side views of the cell of FIG. 2;

FIG. 6 illustrates a cross-section view of a PMOS transistor; and

FIG. 7 illustrates a schematic of the memory cell;

FIG. 8 illustrates an embodiment of programming a cell;

FIG. 9 illustrates an embodiment of reading a cell;

FIG. 10 illustrates an embodiment of erasing one or more cells in an sector;

FIG. 11 illustrates an array of cells.

### DETAILED DESCRIPTION OF THE INVENTION

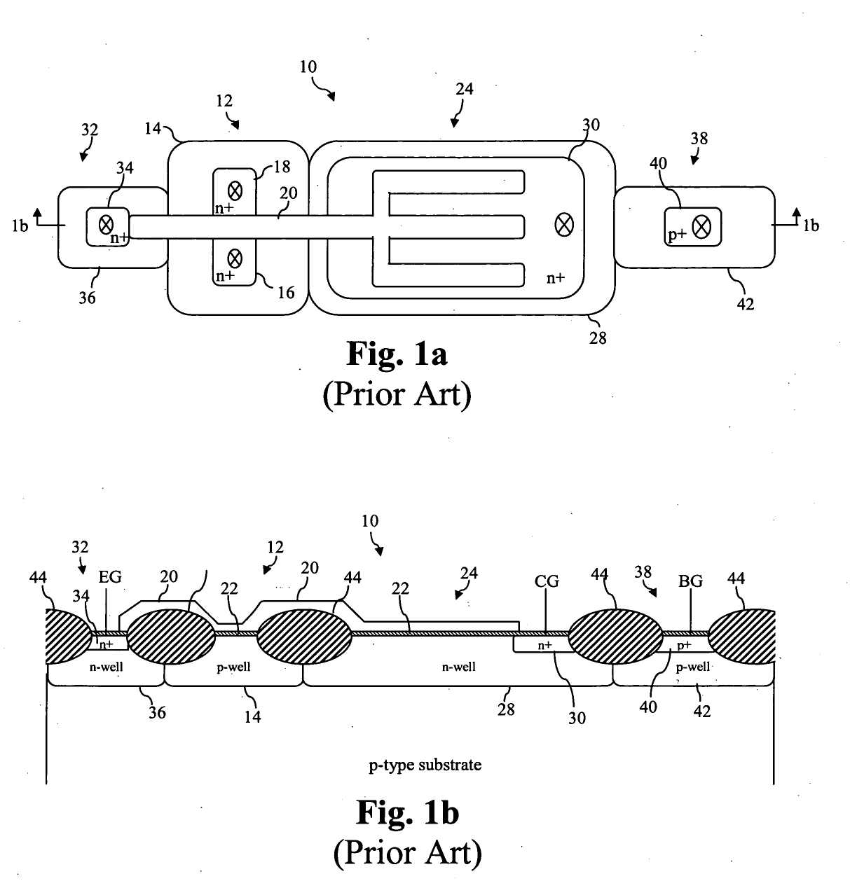

The present invention is best understood in relation to FIGS. 1-7 of the drawings, like numerals being used for like elements of the various drawings.

FIGS. 1a and 1b illustrate a plan view and a cross-sectional side views of a prior art EEPROM memory cell 10. An NMOS transistor 12 formed within a p-well 14 includes n+ type source and drain active regions 16 and 18, respectively, and a polysilicon floating gate 20 separated from the p-well 14 by gate oxide layer 22. The floating gate 20 extends into a capacitor 24. The floating gate 20 overlies an n-well 28, the floating gate being separated from the n-well 28 by gate oxide layer 22. An n+ active region 30 is formed in the n-well 28 in areas not underlying the floating gate 20. An erase gate 32 is formed as an n+ region 34 within an n-well 36. A backgate 38 is formed as a p+ region 40 within a p-well. 42. N-wells and p-wells are separated by field oxide regions 44.

In operation, the EEPROM memory cell 10 is programmed using Fowler-Nordheim electron tunneling by applying a voltage of approximately 13 volts to the control gate (CG), while leaving the erase gate (EG), source 16, drain 18 and backgate 38 grounded. The floating gate 20, oxide layer 22 and n+ active region 30. (along with the n-well 28) form a capacitor 24. Hence, the increase in the voltage at the control gate CG (one plate of capacitor 24) causes an increase in the voltage at the floating gate 20 (the other plate of capacitor 24). The floating gate voltage will rise to about ten volts. Through Fowler-Nordheim electron tunneling, electrons will be drawn from the grounded areas beneath the floating gate 20 to the floating gate itself. When the control gate (CG) is returned to ground, the floating gate will remain at around 2-3 volts.

To read from the EEPROM memory cell 10, a voltage of zero to three volts is placed on the control gate (CG) and a low voltage of around one volt is placed on the drain 18. If the memory cell has been programmed, the voltage on the floating gate will cause an inversion region between the source 16 and drain 18, causing current to flow. If not, current will not be able to flow from source to drain. By measuring the voltage at the source, it can be determined whether or not the memory cell 10 is programmed.

To erase the EEPROM memory cell 10, thirteen volts is applied to the erase gate (EG). Since the erase gate has only a small capacitive relationship with the floating gate, the higher voltage at the active region 34 will draw electrons from the floating gate 22 into the active region 34, thereby removing the charge on the floating gate.

A problem with an EEPROM memory cell of the type shown in FIGS. 1a-b is its size. As described above, a small memory cell size is an extremely important feature in many circumstances.

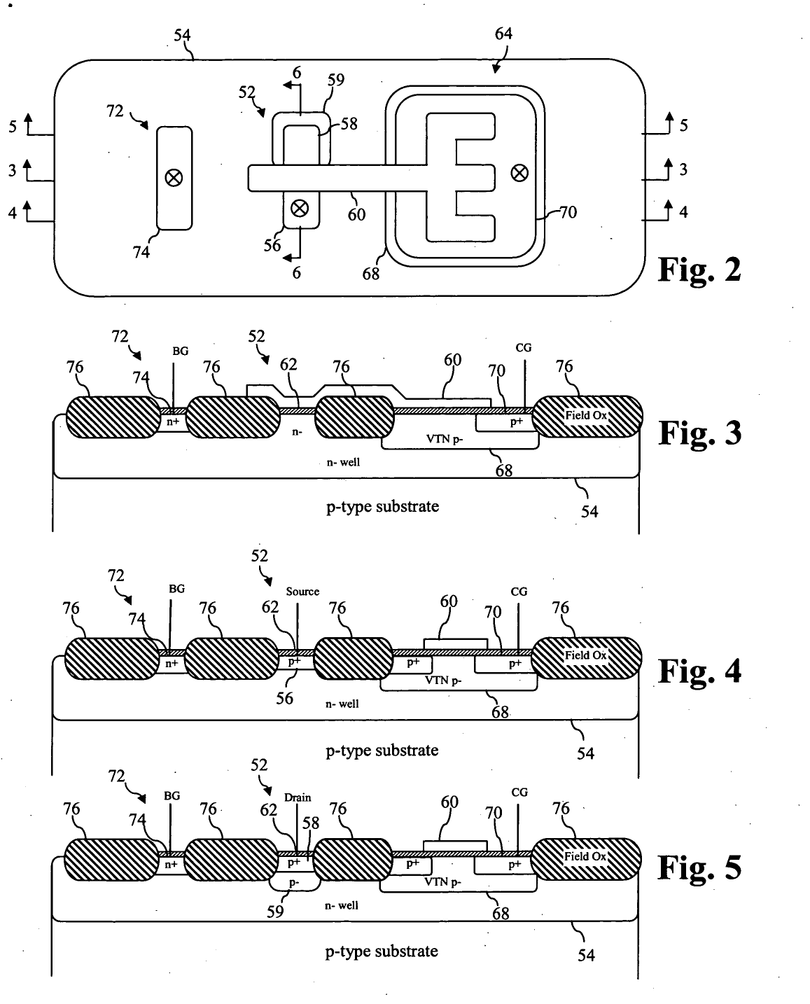

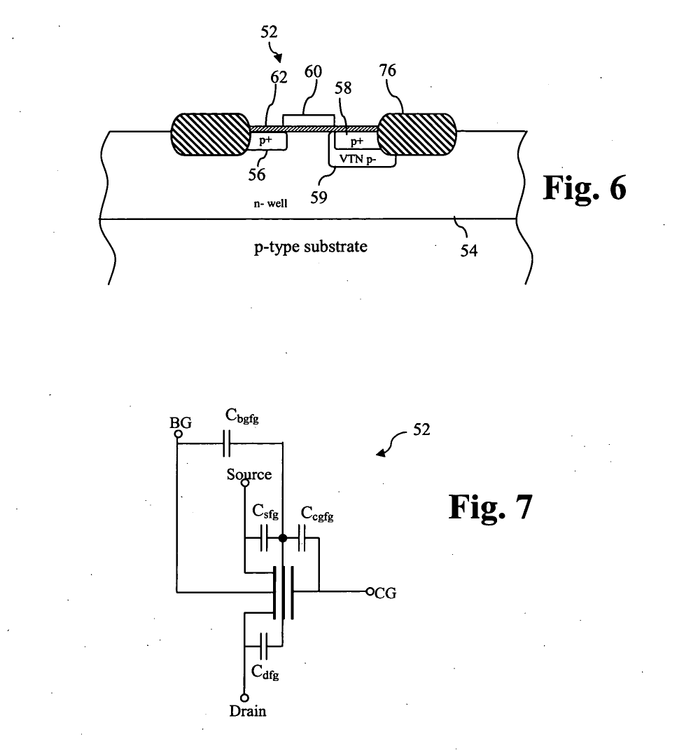

An EEPROM memory cell 50 (which can also be arrayed and used in a flash EEPROM unit) 50 is shown in FIGS. 2-7. FIG. 2 illustrates a plan view and FIGS. 3-5 illustrate cross-sectional side views of the cell 50. FIG. 6 illustrates a cross-section view of a PMOS transistor. FIG. 7 illustrates a simplified schematic representation of the memory cell 50.

Referring to FIGS. 2-6, PMOS transistor 52 formed within an n-well 54 which includes p+ type source and drain active regions 56 and 58, respectively, and a polysilicon floating gate 60 separated from the n-well 54 by gate oxide layer 62. Drain active region 58 is formed in a VTN p− diffusion region 59. The floating gate 60 extends into a capacitor 64. The floating gate 60 overlies an a VTN p− diffusion region 68 formed within n-well 54, the floating gate 60 being separated from the p− diffusion region 68 by gate oxide layer 22. A p+ active region 70 is formed in the p− diffusion region 68 in areas not underlying the floating gate 60. A backgate 72 is formed as an n+ region 74 within n-well 54. Active regions are separated by field oxide regions 76.

The memory cell is shown in a schematic view in FIG. 7. C_{cgfg} is the capacitor formed by the floating gate 60 and the diffused region 68 and active region 70. C_{bgfg} represents the capacitance between the floating gate 60 and the backgate. C_{sfg} and C_{dfg} are the capacitances between the source active region 56 and the floating gate 60 and the drain active region 58 and diffused region 59 and the floating gate 60. When the cell 52 is programmed by applying V_{cg}=−13 volts, then the floating gate voltage V_{fg}=V_{cg}*C_{cgfg}/C_{T}, where C_{T}=C_{cgfg}+C_{dfg}+C_{sfg}+C_{bgfg}.

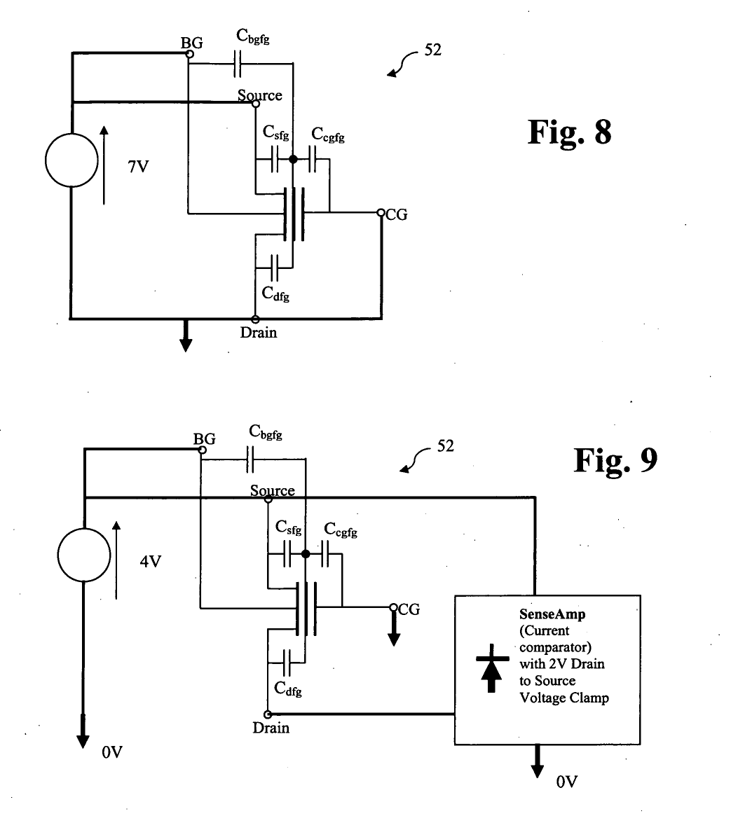

In operation, the floating gate potential serves to invert region under the floating gate 60 to p-type, thus forming a capacitor within a small area; the VTN p− diffused region assists in defining a p region under the floating gate. The memory cell 50 can be programmed either using channel hot electron (CHE) injection or Fowler-Nordheim electron tunneling. Using a CHE approach, −10 volts is applied to the control gate (CG), −6 volts is applied to the drain 58, with the source 56 and backgate 74 grounded. The voltage on the control gate pulls down the voltage on the floating gate 60, due to the capacitance between the floating gate 60 and the p+ active region 70 and the p− diffused region 68. The voltage on the drain 58 causes a current between source and drain, with electrons being attracted to the floating gate 60, the electric field across the control capacitor to aid injection into the floating gate. Hence the floating gate will acquire a voltage which creates an inversion layer between source 56 and drain 58. Alternatively, CHE injection can also be achieved by applying seven volts to the backgate and source relative to the control gate and drain. This is shown in FIG. 8.

Using Fowler-Nordheim electron tunneling, a voltage of −13 volts is applied to the control gate (CG), with the source 56, drain 58 and backgate 74 remaining grounded. The voltage on the control gate pulls down the voltage on the floating gate 60, due to the capacitance between the floating gate 60 and the p+ active region 70 and the p− diffused region 68. The difference in voltage between the floating gate 60 and the grounded areas underlying the floating gate attracts electrons to the floating gate 60. Once again, the floating gate will acquire a voltage which creates an inversion layer between source 56 and drain 58.

The memory cell can be read using a voltage of −3.3 volts on the control gate (CG), and −1 volt on the drain. Alternatively, as shown in FIG. 9, 4 volts may be applied to the source and backgate of the cell while routing the drain and the source to a sense amplifier current comparator circuit. To avoid disturbing the cell's floating gate charge status, a voltage clamp of 2 volts is present between the source and rain of the cell. A ‘programmed cell’ will allow source-to-drain current to flow; whereas an ‘unprogrammed cell’ will have only source to drain leakage current. The reference current used in the sense amplifier is such as to give a true cell status by differentiating between cell leakage current and cell programmed current.

To erase the memory cell 50 using Fowler-Nordheim electron tunneling, a voltage of −13 volts is applied to the drain 58, with the source floating. The control gate (CG) and backgate 72 are grounded. In prior art EEPROMs, a voltage as high as −13 volts would cause junction breakdown; however, with the p− diffused region, the junction breakdown threshold is increased. Therefore, the increased voltage on the drain will cause electrons from the floating gate 60 to flow to the drain 58, thereby discharging the floating gate 60. By leaving the source 56 floating, voltage applied to the drain-will not be reduced by a current between source and drain. In a memory cell array, selected cells can be erased by applying the −13 volts only to the drains of cells 50 to be erased.

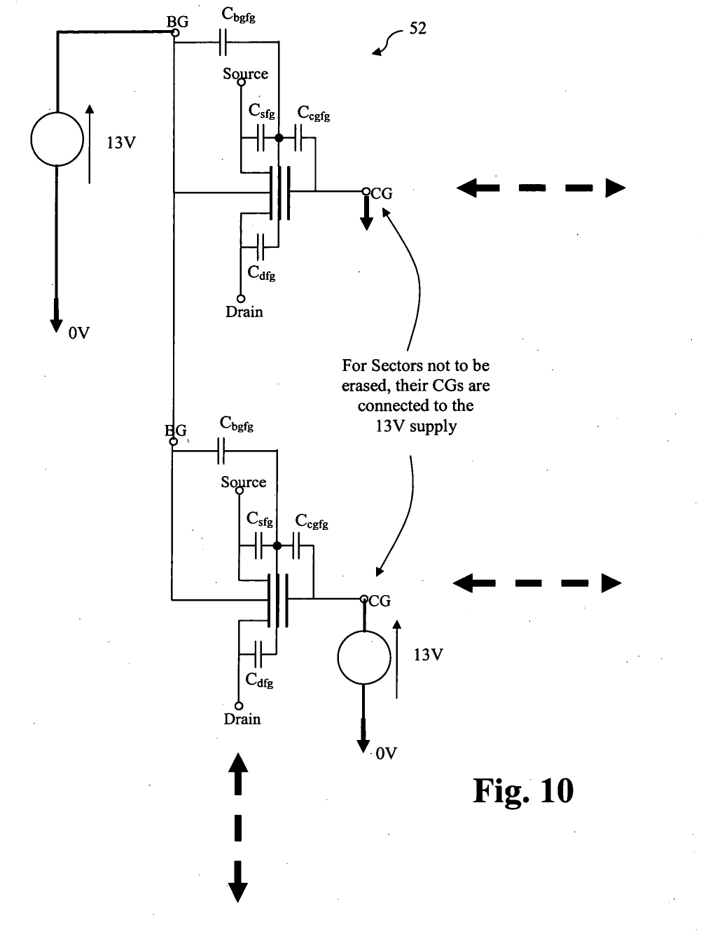

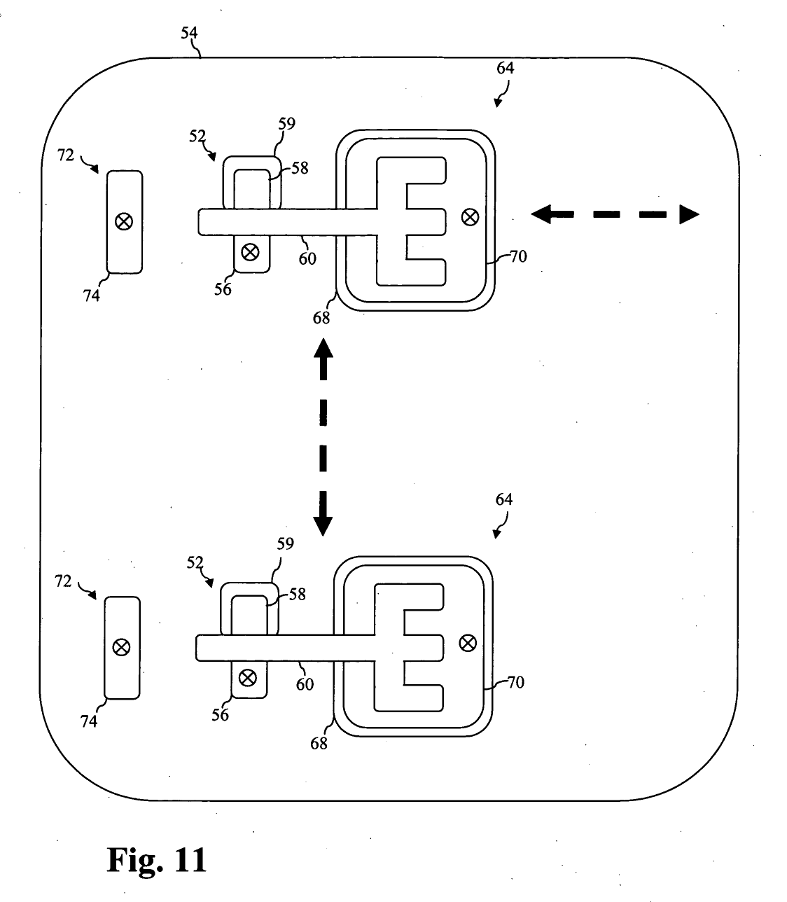

Alternatively, the memory cell 50 can be erased using Fowler-Nordheim tunneling by applying a 13 volt signal on the backgate 74 with the control gate grounded, as shown in FIG. 10. With a differential of about ten volts between the floating gate and the backgate, electrons are drawn from the floating gate into the n-well 54. In a memory cell array (see FIG. 11), sectors may be defined; for example, a sector could be defined as sixteen cells having their control gates coupled together. By applying 13 volts to the control gate of cells which are not to be erased, which would eliminate the voltage differential between the n-well 54 and the floating gate 60, and applying 0 volts to the control gate of those cells to be erased, selective erasure of an array is achieved. In this way, arrays can be reprogrammed without the need of subjecting the cells to UV radiation.

It should be noted that the voltages set forth above can vary based on the processing technology used.

An example of a process flow for forming the memory cell 50 in a P type substrate is as follows:

| SEQ # | DESCRIPTION |
|---|---|
| 1 | LOT FORMATION |
| 2 | NWELL PAD OX |
| 3 | NWELL PATTERN |
| 4 | NWELL IMPLANT |
| 5 | PWELL PATTERN |
| 6 | PWELL IMPLANT |
| 7 | WELL DRIVE |
| 8 | ISO PAD OX |
| 9 | ISO NIT DEP |
| 10 | ACTIVE PATTERN |
| 11 | ACTIVE DRY ETCH |
| 12 | FIELD OX |
| 13 | DUMMY OX |
| 14 | VTN PATTERN |
| 15 | VTN IMPLANT |
| 16 | VTP PATTERN |
| 17 | VTP IMPLANT |
| 18 | GATE OXIDE |
| 19 | GATE POLY DEP (deposition) |
| 20 | GATE PATTERN |
| 21 | GATE ETCH |
| 22 | GATE ETCH CLEAN |
| 23 | POLY OXIDATION |
| 24 | NLDD (lightly doped drain) PATTERN |
| 25 | NLDD IMPLANT |
| 26 | PLDD PATTERN |
| 27 | PLDD IMPLANT |
| 28 | S/W (sidewall) DEP |
| 29 | S/W ETCH |
| 30 | N+ S/D PATTERN |
| 31 | N+ S/D IMPLANT |
| 32 | P+ S/D PATTERN |
| 33 | P+ S/D IMPLANT |
| 34 | SIBLK OX DEP |
| 35 | S/D ANNEAL |
| 36 | RTA S/D ANNEAL |
| 37 | SIBLK PATTERN |
| 38 | SIBLK OX ETCH |
| 39 | TI SPUT |
| 40 | SILICIDE FORM |
| 41 | TI STRIP |
| 42 | SILICIDE ANNEAL |
| 43 | PMD (poly/metal dielectric) NITRIDE DEP |
| 44 | PMD DEP |
| 45 | PMD DENSIFY |
| 46 | PMD CMP |
| 47 | PMD-2 DEP |
| 48 | C/T (contact) PATTERN |
| 49 | C/T DRY ETCH |
| 50 | C/T BAR MET SPUT |
| 51 | C/T SILICIDE FORM |
| 52 | C/T BAR TIN |
| 53 | C/T PLUG DEP |
| 54 | C/T PLUG CMP |
| 55 | MET1 SPUT |
| 56 | MET1 ARC |
| 57 | MET1 PATTERN |
| 58 | MET1 ETCH |
| | P/O (protective overcoat, passivation) HDP |
| 59 | DEP |
| 60 | P/O OX DEP |
| 61 | P/O NIT DEP |
| 62 | P/O PATTERN |
| 63 | P/O ETCH |
| 64 | SINTER |
| 65 | TEST PROBE |

The present invention provides significant advantages over the prior art. First, the memory cell 50 is very compact compared to other EEPROMs which require multiple n-wells. In typical structure such as that shown in FIGS. 1a-b, the field oxide regions are typically on the order of four microns in width, due to the deep (two micron) implants necessary to form the n-wells and p-wells. On the other hand, the smaller VTN p− diffusion areas are much more shallow, requiring field oxide widths of only about 1.5 microns.

Second, the process is compatible with many other process technologies, without requiring additional polysilicon layers, which makes it particularly suited for integration with other devices, such as processors. Third, the cell can be programmed using either Fowler-Nordheim tunneling or hot electron injection. Fourth, the cell supports flash erasure.

It should be noted that while the present invention has been described in connection with p-type diffusion regions formed in an n-well, the principles described herein could be equally applied to diffusions of opposite polarities (i.e., an isolated p-well with an n-type control capacitor, with an NMOS transistor).

Although the Detailed Description of the invention has been directed to certain exemplary embodiments, various modifications of these embodiments, as well as alternative embodiments, will be suggested to those skilled in the art. The invention encompasses any modifications or alternative embodiments that fall within the scope of the claims.

1. A electronically erasable read only memory, comprising:
a capacitor comprising:
a diffusion layer of a first conductivity type formed in a well of a second conductivity type;
an insulating layer overlying the diffusion layer; and
a floating gate overlying the diffusion layer; and
a MOS transistor comprising:
first and second active regions formed in the well, adjacent to an extended portion of the floating gate.

2. The electronically erasable read only memory of claim 1 wherein the first conductivity type is a p type and the second conductivity type is an n type.

3. The electronically erasable read only memory of claim 1 wherein the first conductivity type is an n type and the second conductivity type is a p type.

4. The electronically erasable read only memory of claim 1 and further comprising a second diffusion layer beneath one of the first and second active regions.

5. The electronically erasable read only memory of claim 4 wherein the first active regions comprises a source, the second active region comprises a drain, and the extended portion the floating gate comprises a gate of a MOS transistor, and the second diffusion layer is formed beneath the second active region.

6. A method of forming an electronically erasable read only memory, comprising the steps of:
forming a diffusion layer of a first conductivity type formed in a well of a second conductivity type;
forming an insulating layer overlying the diffusion layer; and
forming a floating gate overlying the diffusion layer; and
forming first and second active regions formed in the well, adjacent to an extended portion of the floating gate.

7. The method of claim 6 wherein the step of forming a diffusion layer comprises the step of forming a diffusion layer of a p conductivity type in a well of an n conductivity type.

8. The method of claim 6 wherein the step of forming a diffusion layer comprises the step of forming a diffusion layer of an n conductivity type in a well of a p conductivity type.

9. The method of claim 6 and further comprising the step of forming a second diffusion layer beneath one of the first and second active regions.

10. The method of claim 9 wherein the first active region comprises a source, the second active region comprises a drain, and the extended portion the floating gate comprises a gate of a MOS transistor, and wherein the step of forming a second diffusion layer comprises the step of forming the second diffusion layer beneath the second active region.
